(19) United States
(12) Patent Application Publication
(10) Pub. No.: US 2016/0043288 A1
(43) Pub. Date: Feb. 11, 2016

(54) LIGHT-EMITTING DIODE MODULE CAPABLE OF REDUCING BLUE-LIGHT ENERGY

(71) Applicant: BRIGHT LED ELECTRONICS CORP., NEW TAIPEI CITY (TW)

(72) Inventors: JEN-TE CHEN, NEW TAIPEI CITY (TW); TING-YUAN CHENG, NEW TAIPEI CITY (TW)

(21) Appl. No.: 14/516,879

(22) Filed: Oct. 17, 2014

(30) Foreign Application Priority Data
Aug. 11, 2014 (TW) 103127534

(51) Int. Cl. H01L 33/50; H01L 27/15; H01L 33/56

(52) U.S. Cl. CPC H01L 33/504; H01L 33/56; H01L 27/15

(57) ABSTRACT

The present invention provides an LED module capable of blue-light energy, which mainly comprises a blue LED chip and a packaging glue. The blue LED chip emits blue light. The packaging glue covers the light-emitting path of the blue LED chip. The packaging glue further includes a fluorescent powder. The amount of the fluorescent powder occupies 10% to 40% of the amount of the packaging glue. After the blue light excites the fluorescent powder, the white light is generated. The hue of the white light falls in hue coordinates (CIE 1931) and 8 nominal CCT ranges in the chromaticity diagram. The present invention controls the proportion of the fluorescent powder in the packaging glue, so that the blue light consumes most of its energy on exciting the fluorescent powders. Thereby, the proportion of the blue light in the white light is fewer.

### FIELD OF THE INVENTION

The present invention relates generally to a light-emitting diode (LED) module, and particularly to an LED module capable of reducing blue-light energy.

### BACKGROUND OF THE INVENTION

Technologies advance with each passing day. In particular, the lighting technologies have made drastic progresses. In recent years, the LED technology has been developed aggressively. LEDs are light-emitting semiconductor electronic devices capable of emitting light spanning visible, infrared, and ultraviolet light. The brightness thereof has also been raised to a substantial level. Their applications are initially focused on indicators and display boards. After white LEDs appeared recently, they are gradually developed to lighting applications.

Nonetheless, the LED is a monochromatic light source. A single LED cannot emit multichromatic light without other auxiliary materials. Thereby, being a single light source, it is not possible that an LED can emit white light. For a general white LED, the white light is formed by combining three monochromatic lights of the three primary colors, namely, blue, green, and red, or by converting monochromatic light using fluorescent powder. Consequently, the overall spectrum will contain the spectra of the three primary colors, which will stimulate the photoreceptors in human eyes and enable the feeling of seeing the white light.

The white LEDs popularized in recent year adopt a single light-emitting unit to emit light with a shorter wavelength such as blue or ultraviolet light. Then the phosphor is used for converting a portion of all of the light to light containing longer wavelengths such as green or red light. The conversion of wavelength is named fluorescence. The principle is that after the photon of a short wavelength (blue, purple, and ultraviolet light) is absorbed by the electron in the fluorescent material such as the phosphor, the electron is excited to a high-energy and unstable excited state. Afterwards, when the electron returns to the original state, a part of the energy is dissipated into heat, while the rest is emitted in the form of photon. Because the energy of the emitted photo is less than the former energy, the wavelength is longer.

In the white LED according to the prior art, the blue light is adopted as the light source. A portion of the blue light excites different fluorescent materials for generating light of other wavelengths such as green and red light. By mixing the green and red light with the blue light not involved in exciting the fluorescent materials, the white light is generated. Nonetheless, this kind of white light is mostly composed by blue light, which has stronger energy and tends to result in blue-light optical injury. This type of optical injury causes reduction in viability, necrosis, and withering of the pigmented epithelium cells (A2E cells), which contains a substantial amount of metabolic waste, in the retina, leading to harms to the eyes.

According to the drawbacks of the prior art, the inventors of the present invention research and improve for reducing the blue-light energy and hence reducing harms to the eyes. Thereby, the present invention provides an LED device capable of reducing blue-light energy. The present invention mainly uses a blue LED chip and a packaging glue. The proportion of fluorescent powder in the packaging glue is controlled. The packaging glue covers the light-emitting path of the blue LED chip. Thereby, the blue light consumes most of its energy on exciting the fluorescent powder and emitting red and green light. The red light and green light combine with the blue light not used in exciting the fluorescent powder and form the white light. Consequently, the blue light shares fewer proportion of the white light, giving a structure having novelty and nonobviousness.

### SUMMARY

An objective of the present invention is to provide an LED module capable of reducing blue-light energy. The LED module emits white light mixed by multichromatic light. By controlling the concentration range of the fluorescent powder, the blue-light energy contained in the white light can be reduced. In addition, the hue of the white light is located in the hue coordinates (CIE 1931) and within 8 nominal correlated color temperature ranges in the chromaticity diagram.

In order to achieve the objective described above, the present invention provides an LED module capable of reducing blue-light energy, which mainly comprises a substrate, a blue LED chip, and a packaging glue. The blue LED chip is fixed on the substrate and emits blue light. The packaging glue covers the light-emitting path of the blue LED chip. The packaging glue further comprises at least a fluorescent powder. The amount of the fluorescent powder occupies 10% to 40% of the amount of the packaging glue. After the blue light excites the fluorescent powder, the white light is generated. The hue of the white light is located in the hue coordinates (CIE 1931) and within 8 nominal correlated color temperature ranges.

Moreover, the present invention provides an LED module capable of reducing blue-light energy, which mainly comprises a substrate, a red LED chip, a blue LED chip, and a packaging glue. The red LED chip is fixed on the substrate and emits red light. The blue LED chip is fixed on one side of the red LED chip and emits blue light. The packaging glue covers the light-emitting path of the blue LED chip. The packaging glue further comprises at least a fluorescent powder. The amount of the fluorescent powder occupies 10% to 40% of the amount of the packaging glue. After the blue light excites the fluorescent powder, the white light is generated. The hue of the white light is located in the hue coordinates (CIE 1931) and within 8 nominal correlated color temperature ranges.

According to an embodiment of the present invention, the wavelength of the blue light is above 450 nm.

According to an embodiment of the present invention, the fluorescent powder is a green fluorescent powder and a red fluorescent powder.

According to an embodiment of the present invention, the fluorescent powder is a green fluorescent powder.

According to an embodiment of the present invention, the green fluorescent powder contains lutetium (Lu) or gallium (Ga).

According to an embodiment of the present invention, the present invention further comprises a sleeve member disposed on the substrate and forming an accommodating space. The blue LED chip is disposed in the accommodating space.

According to an embodiment of the present invention, the present invention further comprises a sleeve member disposed on the substrate and forming an accommodating space. The blue LED chip and the red LED chip are disposed in the accommodating space.

### BRIEF DESCRIPTION OF THE DRAWINGS

FIG. 1A shows a structural diagram of the LED according the first embodiment of the present invention;

FIG. 1B shows a schematic diagram of the LED according the first embodiment of the present invention;

FIG. 1C shows curves of intensity vs. blue-light wavelength according the first embodiment of the present invention;

FIG. 1D shows curves of intensity vs. blue-light wavelength according the first embodiment of the present invention;

FIG. 1E shows curves of intensity vs. blue-light wavelength according the first embodiment of the present invention;

FIG. 1F shows a chromaticity diagram according the first embodiment of the present invention;

FIG. 2A shows a structural diagram of the LED according the second embodiment of the present invention;

FIG. 2B shows a schematic diagram of the LED according the second embodiment of the present invention;

FIG. 3A shows a structural diagram of the LED according the third embodiment of the present invention; and

FIG. 3B shows a schematic diagram of the LED according the third embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

The present invention improves the white LED according to the prior art, which emits higher-energy light harmful to the eyes. The white LEDs popularized in recent year adopt a single light-emitting unit to emit light with a shorter wavelength such as blue or ultraviolet light. Then fluorescent materials (green and red fluorescent powders) are used and excited by a portion of the higher-energy light, giving light with longer wavelength and lower energy. In addition, the other portion of the higher-energy light is reserved. Then the light with longer wavelength and lower energy is mixed with the light with shorter wavelength, higher energy, and unused in exciting the fluorescent powders, and thus generating the white light. The white light of the LEDs according to the prior art is generated by blue LED chips (450 nm˜500 nm) or ultraviolet LED chips (380 nm˜450 nm). Nonetheless, while using the white light generated by the LEDs as the lighting source, due to its mixture nature and inclusion of blue-light energy, there is a risk of damage on the retinal cells of humans.

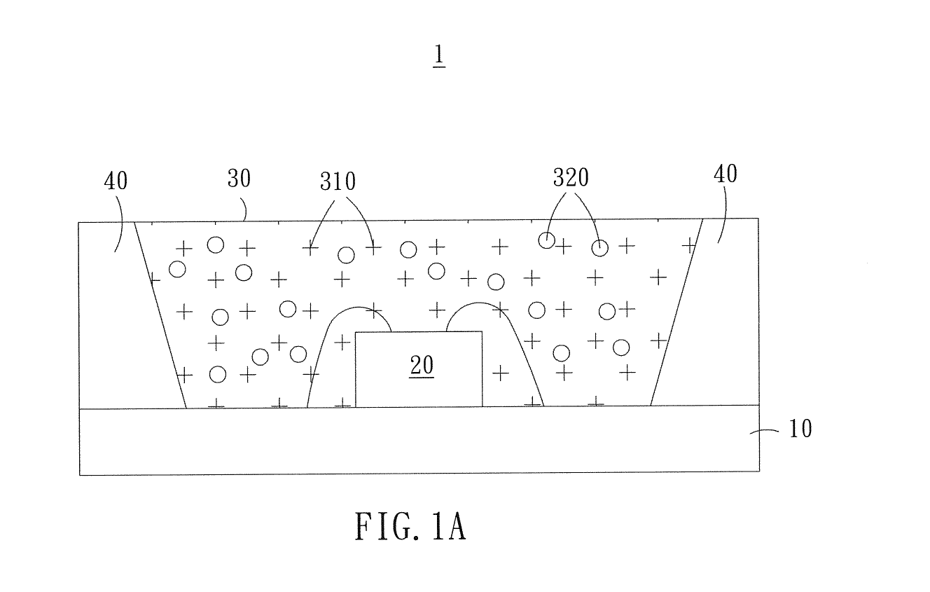

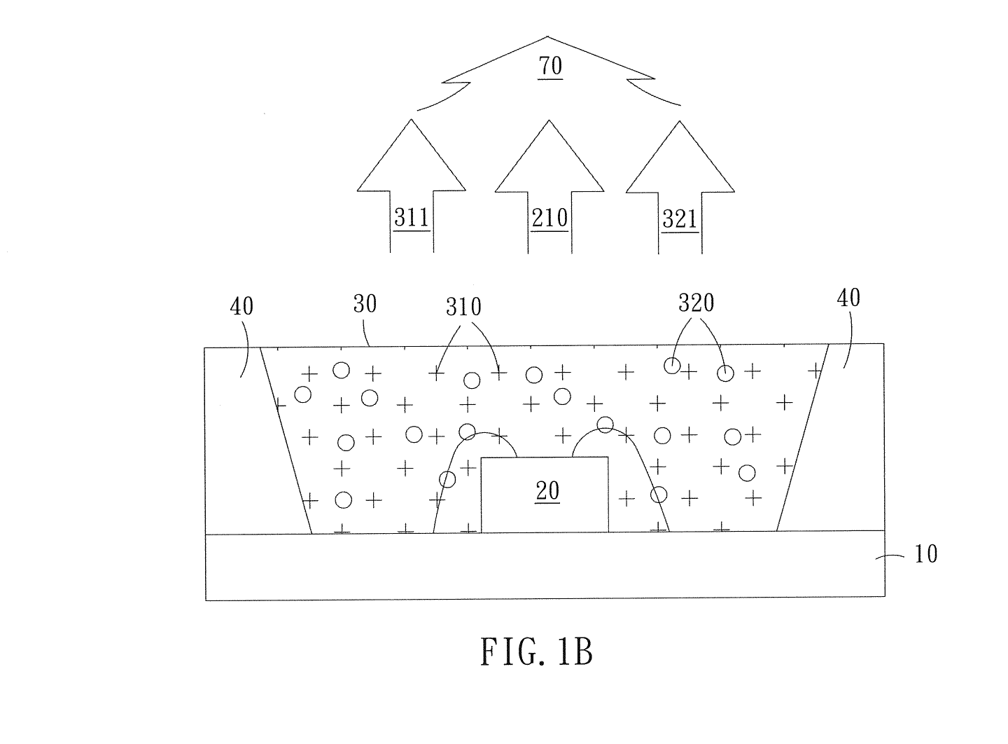

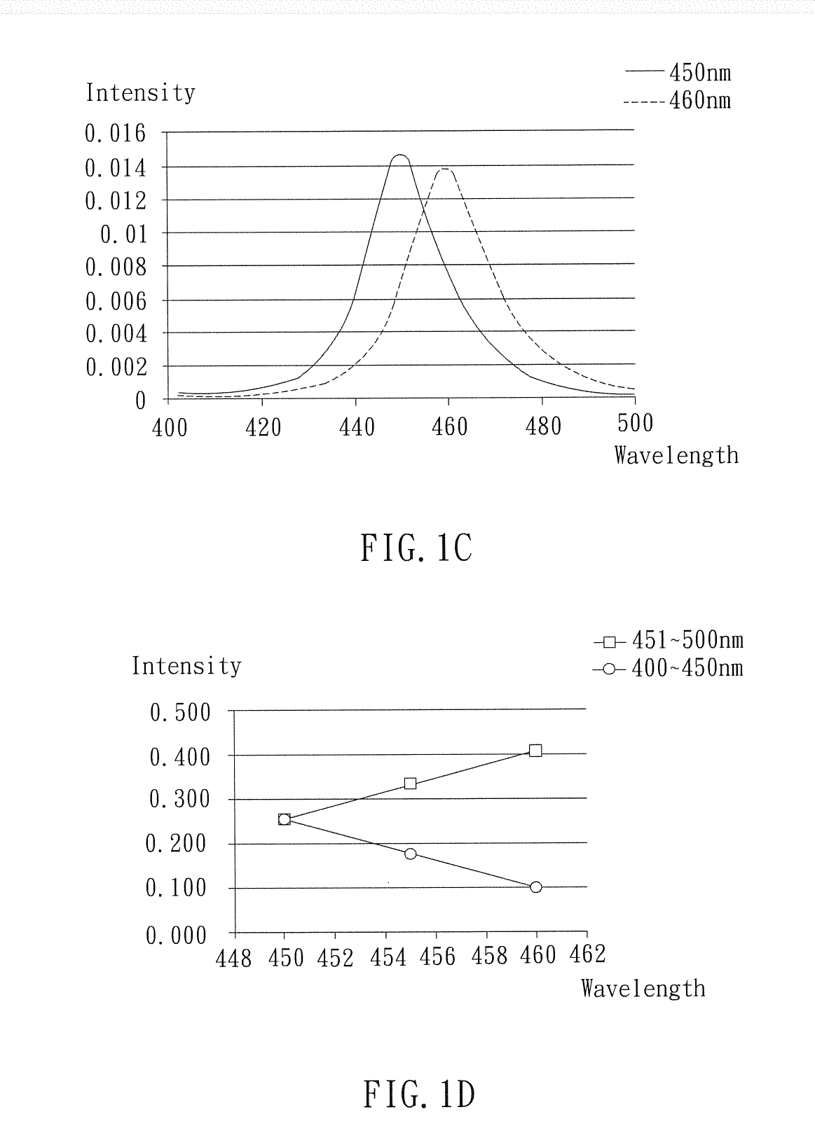

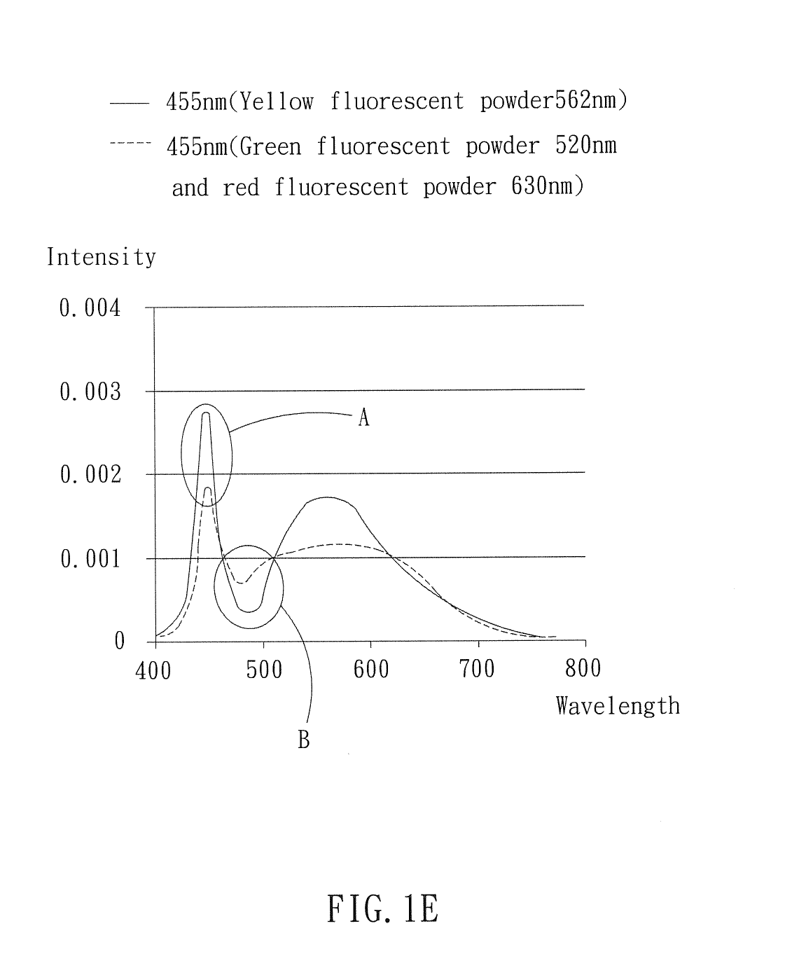

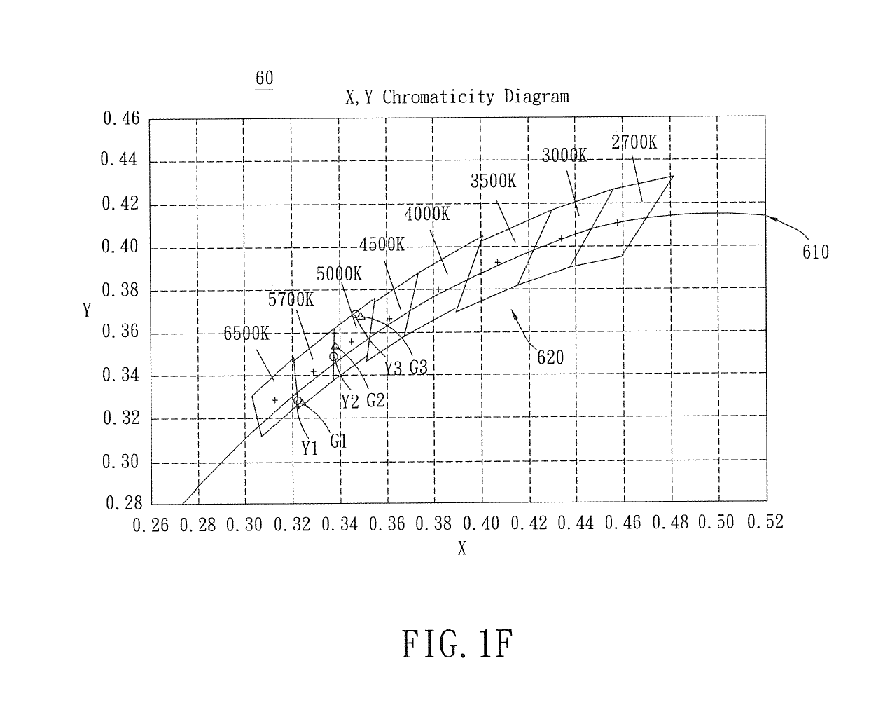

Please refer to FIG. 1A and FIG. 1B, which show structural diagrams of the LED according the first embodiment of the present invention. As shown in the figures, the present embodiment provides a white LED module 1, which comprises a substrate 10, a blue LED chip 20, a packaging glue 30, and a sleeve member 40. In addition, the packaging glue 30 further comprises at least a fluorescent powder 300, which includes a green fluorescent powder 310 and a red fluorescent powder 320.

The sleeve member 40 is disposed on the substrate 10 and thus forming an accommodating space 410. The blue LED chip 20 is disposed in the accommodating space 410 and fixed on the substrate 10. The packaging glue 30 covers the light-emitting path of the blue LED chip 20. The packaging glue 30 includes the green fluorescent powder 310 and the red fluorescent powder 320. Besides, the total amount of the green fluorescent powder 310 and the red fluorescent powder 320 occupy 10% to 40% of the amount of the packaging glue 30.

Please refer to FIG. 1C and FIG. 1D. After testing according to the present embodiment, the differences between blue LED chips 20 with different wavelengths in two bands of 400 nm˜450 nm and 450 nm˜500 nm are shown. Please refer to Table 1 as well. The blue LED chip 20 emits blue light 210. According to the testing spectrum, when the blue LED chip 20 with a wavelength of 450 nm is adopted, the difference in intensity between the band 380 nm˜450 nm and the band 451 nm˜500 nm is not significant. When the blue LED chip 20 with a wavelength of 455 nm is adopted, the intensity is approximately 70% of the intensity of the blue LED chip 20 with a wavelength of 450 nm in the band of 451 nm˜500 nm, but the intensity increases by approximately 30% of the intensity of the blue LED chip 20 with a wavelength of 450 nm in the band of 451 nm˜500 nm. When the blue LED chip 20 with a wavelength of 460 nm is adopted, the intensity is approximately 40% of the intensity of the blue LED chip 20 with a wavelength of 450 nm in the band of 400 nm˜450 nm, but the intensity increases by approximately 60% of the intensity of the blue LED chip 20 with a wavelength of 450 nm in the band of 451 nm˜500 nm.

According to the data in Table 1 and FIGS. 1C and 1D, it is known that when the wavelength of the blue LED chip 20 is 450 nm, its intensity starts to decrease gradually in the band 400 nm˜450 nm. The intensity of the blue LED chip 20 decreases apparently around 455 nm compared with around 450 nm. In addition, the emitted blue-light 210 energy is sufficient for exciting the green and red fluorescent powders 310, 320. Thereby, according to the present invention, the wavelength of the blue light is set between 450 nm and 460 nm; the preferred wavelength of the blue light is 455 nm.

TABLE 1

| | | | Difference | | Difference |
|---|---|---|---|---|---|
| | | | between the | | between the |
| | 450 nm | 455 nm | values of 455 | 460 nm | values of 460 |
| Wavelength | Intensity | Intensity | and 450 | Intensity | and 450 |
| 380~450 | 0.25543 | 0.175396 | 68.67% | 0.09936 | 38.90% |
| 451~500 | 0.25383 | 0.336573 | 132.60% | 0.40931 | 161.25% |

As described above, the wavelength of the blue light 210 is set between 450 nm and 460 nm; the preferred wavelength of the blue light 210 is 455 nm. As the blue light 210 passes through the packaging glue 30, a portion of the blue light 210 will be dissipated in exciting the green fluorescent powder 310 and generating blue-green light 311 (blue light plus the green fluorescent powder), while the other portion of the blue light 210 will be dissipated in exciting the red fluorescent powder 320 and generating purple-red light 321 (blue light plus the red fluorescent powder). According to the present invention, by controlling the total amount of the green and red fluorescent powders 310, 320 contained in the packaging glue 30 to be above 10% of the amount of the packaging glue 30, the blue LED chip 20 has to consume a substantial amount of the energy of the blue light 210 for exciting the green and red fluorescent powders 310, 320, thus reducing the energy of the blue light 210. Then the blue-green light 311, the purple-red light 321, and the blue light 210 are mixed to form white light 70. Thereby, the blue light 210 contained in the white light 70 is less than the blue light contained in the white light 70 according to the prior art.

Please refer to FIG. 1E. The blue LED chip 20 emits blue light 210. The blue LED chip 20 can be used with the Yag-series yellow fluorescent powder or the Luag-series green fluorescent powder and the red fluorescent powder. When the light-emitting path of the blue LED chip 20 is covered by a packaging glue 30, which contains a yellow fluorescent powder, the blue LED chip 20 emits blue light 210 to excite the yellow fluorescent powder and thus emitting the white light 70, shown as the solid line in the figure. The light-emitting path of the blue LED chip 20 is covered by the Luag-series green fluorescent powder and the red fluorescent powder. When the light-emitting path of the blue LED chip 20 is covered by a packaging glue 30, which contains a green fluorescent powder 310 and a red fluorescent powder 320, the blue LED chip 20 emits the blue light 210 to excite the green fluorescent powder 310 and the red fluorescent powder 320, and thus emitting the white light 70, shown as the dashed line in the figure.

As shown in FIG. 1E, a region A and a region B are indicated. In the region A, the overall light intensity emitted by the blue LED chip 20 added with the yellow fluorescent powder is stronger than that added with the green and red fluorescent powders 310, 320 in the blue-light band (430 nm˜480 m). In the region B, the overall light intensity emitted by the blue LED chip 20 added with the yellow fluorescent powder is weaker than that added with the green and red fluorescent powders 310, 320 off the blue-light band (480 nm˜510 nm). The above result is because the blue LED chip 20 added with the green and red fluorescent powders 310, 320 converts a portion of the photo energy of the blue light 210 to the band in the region B, so that the photo energy of the blue light 210 in the region A is weaker and the wavelength off the blue-light band in the region B is stronger. Thereby, the Luag-series green fluorescent powder 310 and red fluorescent powder 320 are selected.

Next, please refer to FIG. 1F, which shows a chromaticity diagram according the first embodiment of the present invention. As shown in the figure, in the hue coordinates 60 (CIE 1931), there is a planckian curve 610. Along the path of the planckian curve 610, 8 nominal correlated color temperature (nominal CCT) ranges 620 are defined. The nominal CCT ranges 620 are quadrangles. People cannot differentiate colors, namely, the (x, y) coordinates contained in each quadrangle, within each nominal CCT range 620. Colors in the same range can be regarded as the same color. The 8 nominal CCT ranges 620 in the figure are the values as follows. For 2700K, the nominal CCT range is circumscribed by the coordinates (0.4813, 0.4319), (0.4562, 0.4260), (0.4373, 0.3893), and (0.4593, 0.3944). For 3000K, the nominal CCT range is circumscribed by the coordinates (0.4562, 0.4260), (0.4299, 0.4165), (0.1417, 0.3814), and (0.4373, 0.3893). For 3500K, the nominal CCT range is circumscribed by the coordinates (0.4299, 0.4165), (0.3996, 0.4015), (0.3889, 0.3690), and (0.4147, 0.3814). For 4000K, the nominal CCT range is circumscribed by the coordinates (0.4006, 0.4044), (0.3736, 0.3874), (0.3670, 0.3578), and (0.3898, 0.3716). For 4500K, the nominal CCT range is circumscribed by the coordinates (0.3736, 0.3874), (0.3546, 0.3736), (0.3512, 0.3465), and (0.3670, 0.3578). For 5000K, the nominal CCT range is circumscribed by the coordinates (0.3551, 0.3760), (0.3376, 0.3616), (0.3366, 0.3369), and (0.3515, 0.3487). For 5700K, the nominal CCT range is circumscribed by the coordinates (0.3376, 0.3616), (0.3207, 0.3462), (0.3222, 0.3243), (0.3366, 0.3369). For 6500K, the nominal CCT range is circumscribed by the coordinates (0.3205, 0.3481), (0.3028, 0.3304), (0.3068, 0.3113), and (0.3221, 0.3261).

In addition, the hue coordinates 60 and the nominal CCT ranges 620 provide a standard for regulating production of LED products. They can be used as a basis for reducing energy consumption and emission of the greenhouse effect gases from power plants.

Furthermore, please refer to the data in Table 2 as shown below. When the Yag-series yellow fluorescent powder is selected, after the blue light 210 excites the yellow fluorescent powder, the white light 70 is generated. If the white light 70 is to be confined within the nominal CCT ranges 620, then the amount of the yellow fluorescent powder should occupy 5% to 10% of the amount of the packaging glue 30, so that the emitted white light 70 can fall within the hue coordinates 60 (CIE 1931). For example, when the amount of the yellow fluorescent powder is 5%, its coordinates will be Y1(0.323, 0.326); when the amount of the yellow fluorescent powder is 10%, its coordinates will be Y3(0.3473, 0.3683).

When the Luag-series green fluorescent powder 310 and red fluorescent powder 320 are selected in combination, after the blue light 210 excites the combination of the green fluorescent powder 310 and red fluorescent powder 320, the white light 70 is generated. If the white light 70 is to be confined within the nominal CCT ranges 620, then the total amount of the green fluorescent powder 310 and red fluorescent powder 320 should occupy 10% to 40% of the amount of the packaging glue 30, so that the emitted white light 70 can fall within the hue coordinates 60 (CIE 1931). For example, when the total amount of the green fluorescent powder 310 and red fluorescent powder 320 is 10%, its coordinates will be G1(0.3223, 0.3269); when the total amount of the green fluorescent powder 310 and red fluorescent powder 320 is 40%, its coordinates will be G3(0.3462, 0.3688).

As described above, the green fluorescent powder 310 is the Luag-series green fluorescent powder. The excitation efficiency by the blue light 210 for the Luag-series green fluorescent powder is lower than that for the Yag-series yellow fluorescent powder. Thereby, more blue light 210 is required for exciting the green fluorescent powder 310. In other words, compared with the yellow fluorescent powder 310, the combination of the green and red fluorescent powders 310, 320 requires a higher proportion for achieving the same effect. Thereby, within the range of the hue coordinates 60 (CIE 1931), the combination of the green and red fluorescent powders 310, 320 dissipate more energy. Besides, by taking advantage of higher proportion of the combination of the green and red fluorescent powders 310, 320 in the packaging glue 30, the transmissivity of the blue light 210 is lower, and thus decreasing the energy intensity of the blue light 210. In addition, the green fluorescent powder 310 contains Lu, for example, Lu₃Al₅O₁₂:Ce, or contains Ga, for example, (Y,Ce)₃(Ga,Al)₅O₁₂.

TABLE 2

| | x | y | CCT | CRI | CRI09 |
|---|---|---|---|---|---|
| | Green powder 520 nm Red + powder 630 nm (10%~40%) | | | | |
| G1 | 0.3223 | 0.3269 | 6005 | 92 | 60 |
| G2 | 0.3375 | 0.3476 | 5292 | 90.3 | 47.1 |
| G3 | 0.3462 | 0.3688 | 5017 | 86.9 | 27.8 |
| | 455 nm Yag Yellow powder (5%~10%) | | | | |
| Y1 | 0.323 | 0.326 | 5975 | 74 | −4.6 |
| Y2 | 0.3376 | 0.3514 | 5293 | 71 | −23.5 |
| Y3 | 0.3473 | 0.3683 | 4976 | 69.2 | −33.6 |

According to the above description, the white LED module 1 according to the present embodiment uses the blue LED chip 20 as the major light-emitting member. The wavelength of the emitted blue light 210 is confined between 450 nm and 460 nm. Preferably, the wavelength of the blue light 210 is 455 nm. Moreover, the packaging glue 30 containing the Luag-series green fluorescent powder 310 and the red fluorescent powder 320 covers the light-emitting path of the blue LED chip 20. The total amount of the green and red fluorescent powder 310, 320 is controlled between 10% and 40% of the amount of the packaging glue 30. Thereby, the energy of the blue light 210 in the emitted white light 70 can be hence reduced by controlling the type and proportion of the fluorescent powders for the blue LED chip 20.

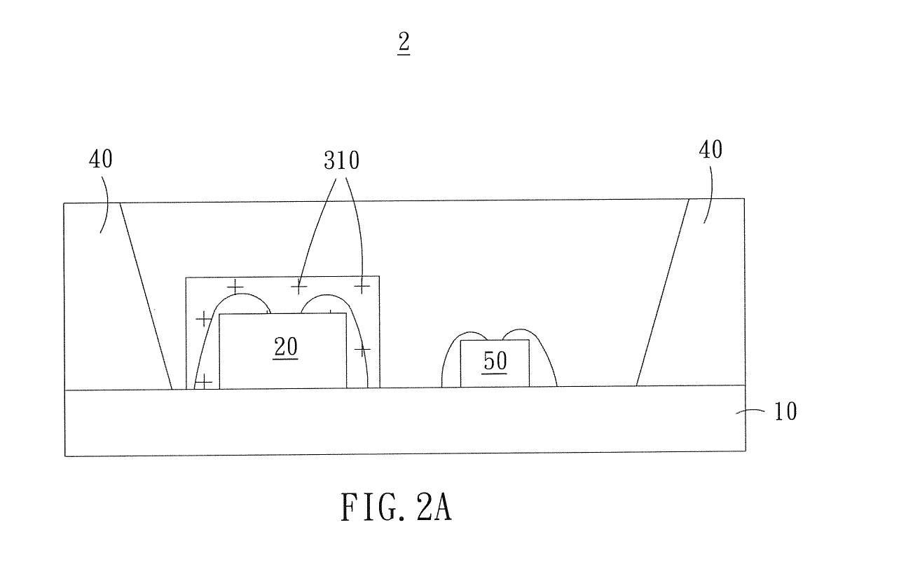

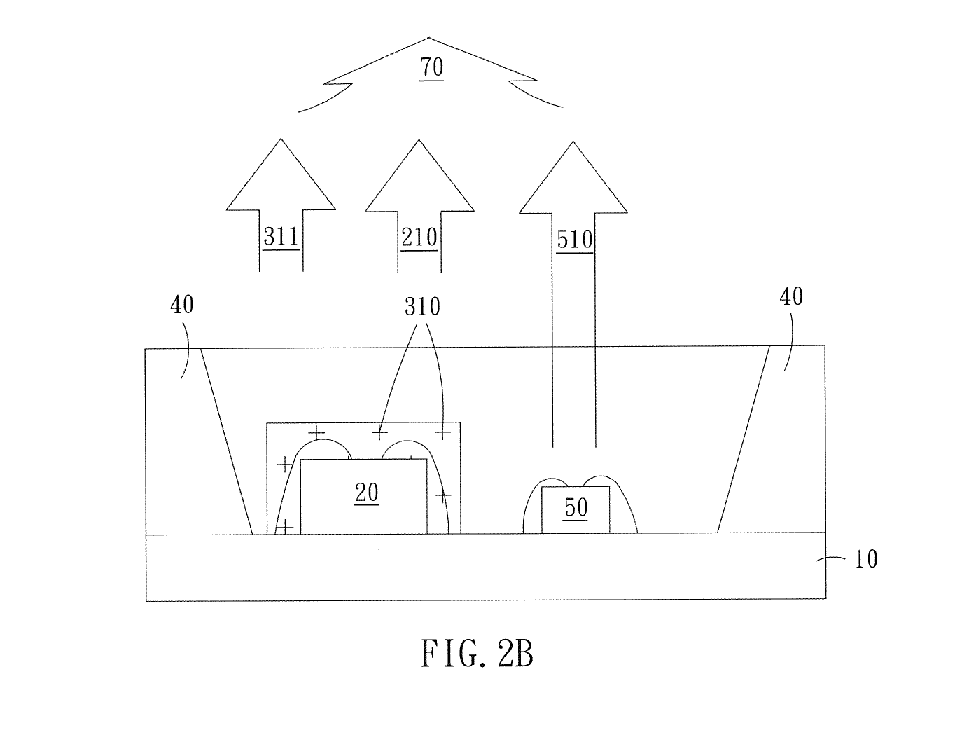

Please refer to FIG. 2A and FIG. 2B, which show a structural diagram and a schematic diagram of the LED according the second embodiment of the present invention. As shown in the figures, the present embodiment provides a white LED module 2, which comprises a substrate 10, a blue LED chip 20, a packaging glue 30, and a sleeve member 40. In addition, the packaging glue further includes a green fluorescent powder 310.

The sleeve member 40 is disposed on the substrate 10 and thus forming an accommodating space 410. A red LED chip 50 is disposed on the accommodating space 410 and fixed on the substrate 10. The red LED chip 50 emits red light. The blue LED chip 20 is fixed on one side of the red LED chip 50 and emits blue light with a wavelength between 450 nm and 460 nm. Besides, the packaging glue 30 covers the light-emitting path of the blue LED chip 20. The packaging glue 30 includes the green fluorescent powder 310. The amount of the green fluorescent powder 310 occupies 10% to 40% of the amount of the packaging glue 30. After the blue light 210 excites the fluorescent powder, the white light 70 is generated. The hue of the white light is located in the hue coordinates 60 (CIE 1931) and within 8 nominal CCT ranges 620.

The difference between the white LED module 2 according to the second embodiment of the present invention and the white LED module 1 according to the first embodiment is that the latter uses the blue light 210 to excite the red fluorescent powder 320 for generating the purple-red light 321, and hence compensating insufficiency in the primary colors while mixing the white light 70. Contrarily, the second embodiment uses the red LED chip 50 directly for providing the red light 510, instead of using the blue light 210 to excite the red fluorescent powder 320.

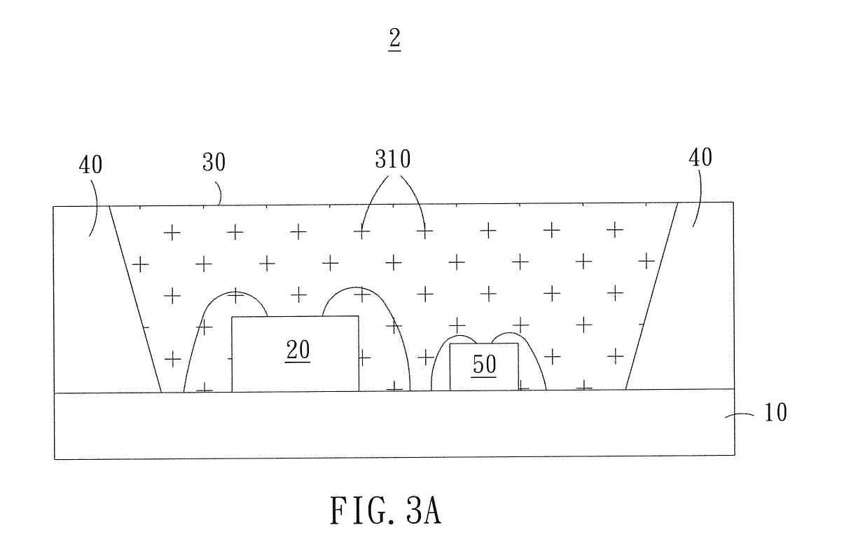

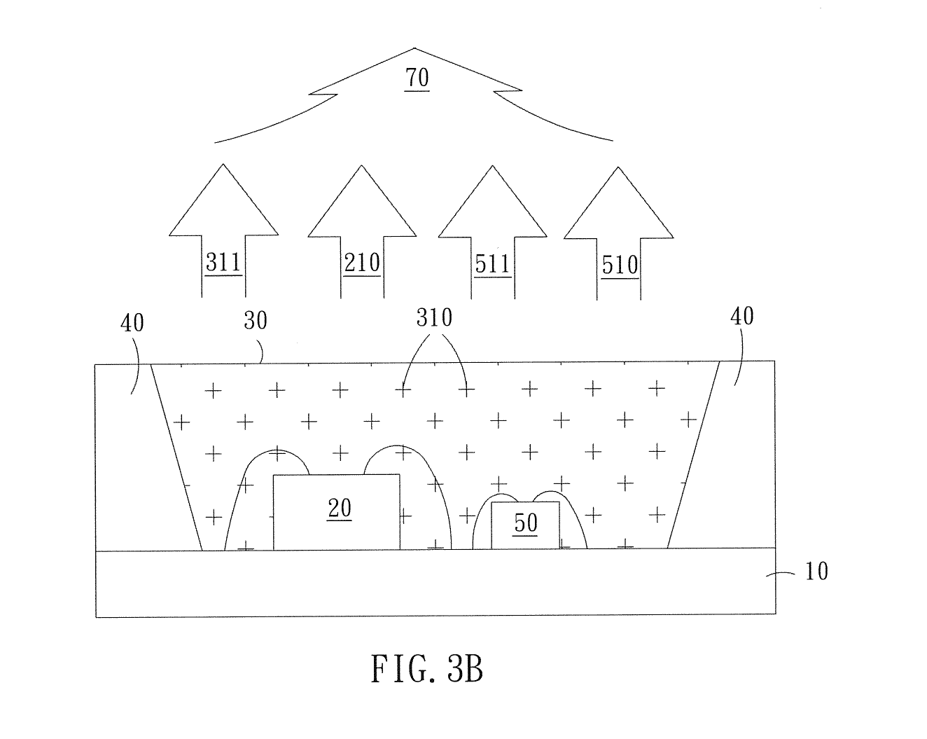

Please refer to FIG. 3A and FIG. 3B, which show a structural diagram and a schematic diagram of the LED according the third embodiment of the present invention. As shown in the figures, the difference between the third embodiment and the second embodiment is on the coverage of the packaging glue 30. The packaging glue 30 according to the second embodiment covers the light-emitting path of the blue LED chip 20, while the packaging glue 30 according to the third embodiment covers the light-emitting path of the blue LED chip 20 and the light-emitting path of the red LED chip 50. Thereby, the red LED chip 50 not only emits the red light 510 but also excites a portion of the green fluorescent powder 320 for generating the yellow light 511 (red light plus green fluorescent powder). Except for the difference described above, the structures according to the third and second embodiments are identical.

To sum up, the present invention provides an LED module capable of blue-light energy, which mainly comprises a substrate, a blue LED chip, and a packaging glue. The blue LED chip is disposed on the substrate. The packaging glue covers the light-emitting path of the blue LED chip. The packaging glue further includes a fluorescent powder. The amount of the fluorescent powder occupies 10% to 40% of the amount of the packaging glue. After the blue light excites the fluorescent powder, the white light 70 is generated. The hue of the white light 70 falls in hue coordinates (CIE 1931) and 8 nominal CCT ranges in the chromaticity diagram. In addition, the Luag-series green fluorescent powder can reduce the blue-light energy effectively, making it less harmful to the eyes after mixing to the white light. And the color rendering index can be controlled between 80 and 95 according to the requirement of a user. Moreover, the red fluorescent powder can be replaced by a red LED chip. By controlling the proportion of the amount of the Luag-series green fluorescent powder contained in the packaging glue to be 10% to 40%, the same effect as above can be achieved.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A light-emitting diode module capable of reducing blue-light energy, comprising:
a substrate;
a blue light-emitting diode chip, fixed on said substrate, and emitting blue light; and
a packaging glue, covering the light-emitting path of said blue light-emitting diode chip, further including a fluorescent powder, the amount of said fluorescent powder occupying 10% to 40% of the amount of the packaging glue, said blue light exciting said fluorescent powder for generating white light, and the hue of said white light located in hue coordinates (CIE 1931) and eight nominal correlated color temperature ranges on the chromaticity diagram.

2. The light-emitting diode module capable of reducing blue-light energy of claim 1, wherein the wavelength of said blue light is above 450 nm.

3. The light-emitting diode module capable of reducing blue-light energy of claim 1, wherein said fluorescent powder includes a green fluorescent powder and a red fluorescent powder.

4. The light-emitting diode module capable of reducing blue-light energy of claim 3, wherein said green fluorescent powder contains lutetium or gallium.

5. The light-emitting diode module capable of reducing blue-light energy of claim 1, and further comprising a sleeve member, disposed on said substrate for forming an accommodating space, and said blue light-emitting diode chip disposed in said accommodating space.

6. The light-emitting diode module capable of reducing blue-light energy of claim 1, wherein said nominal correlated color temperature range for 2700K is circumscribed by the coordinates (0.4813, 0.4319), (0.4562, 0.4260), (0.4373, 0.3893), and (0.4593, 0.3944); said nominal correlated color temperature range for 3000K is circumscribed by the coordinates (0.4562, 0.4260), (0.4299, 0.4165), (0.1417, 0.3814), and (0.4373, 0.3893); said nominal correlated color temperature range for 3500K is circumscribed by the coordinates (0.4299, 0.4165), (0.3996, 0.4015), (0.3889, 0.3690), and (0.4147, 0.3814); said nominal correlated color temperature range for 4000K is circumscribed by the coordinates (0.4006, 0.4044), (0.3736, 0.3874), (0.3670, 0.3578), and (0.3898, 0.3716); said nominal correlated color temperature range for 4500K is circumscribed by the coordinates (0.3736, 0.3874), (0.3546, 0.3736), (0.3512, 0.3465), and (0.3670, 0.3578); said nominal correlated color temperature range for 5000K is circumscribed by the coordinates (0.3551, 0.3760), (0.3376, 0.3616), (0.3366, 0.3369), and (0.3515, 0.3487); said nominal correlated color temperature range for 5700K is circumscribed by the coordinates (0.3376, 0.3616), (0.3207, 0.3462), (0.3222, 0.3243), (0.3366, 0.3369); and said nominal correlated color temperature range for 6500K is circumscribed by the coordinates (0.3205, 0.3481), (0.3028, 0.3304), (0.3068, 0.3113), and (0.3221, 0.3261).

7. A light-emitting diode module capable of reducing blue-light energy, comprising:
a substrate;
a red light-emitting diode chip, fixed on said substrate, and emitting red light;
a blue light-emitting diode chip, fixed on one side of said red light-emitting diode chip, and emitting blue light; and
a packaging glue, covering the light-emitting path of said blue light-emitting diode chip, further including a fluorescent powder, the amount of said fluorescent powder occupying 10% to 40% of the amount of the packaging glue, said blue light exciting said fluorescent powder for generating white light, and the hue of said white light located in hue coordinates (CIE 1931) and eight nominal correlated color temperature ranges on the chromaticity diagram.

8. The light-emitting diode module capable of reducing blue-light energy of claim 7, wherein said packaging glue further covers the light-emitting path of said red light-emitting diode chip.

9. The light-emitting diode module capable of reducing blue-light energy of claim 7, wherein the wavelength of said blue light is above 450 nm.

10. The light-emitting diode module capable of reducing blue-light energy of claim 7, wherein said fluorescent powder is a green fluorescent powder containing lutetium or gallium.

11. The light-emitting diode module capable of reducing blue-light energy of claim 7, and further comprising a sleeve member, disposed on said substrate for forming an accommodating space, and said blue light-emitting diode chip disposed in said accommodating space.

12. The light-emitting diode module capable of reducing blue-light energy of claim 7, wherein said nominal correlated color temperature range for 2700K is circumscribed by the coordinates (0.4813, 0.4319), (0.4562, 0.4260), (0.4373, 0.3893), and (0.4593, 0.3944); said nominal correlated color temperature range for 3000K is circumscribed by the coordinates (0.4562, 0.4260), (0.4299, 0.4165), (0.1417, 0.3814), and (0.4373, 0.3893); said nominal correlated color temperature range for 3500K is circumscribed by the coordinates (0.4299, 0.4165), (0.3996, 0.4015), (0.3889, 0.3690), and (0.4147, 0.3814); said nominal correlated color temperature range for 4000K is circumscribed by the coordinates (0.4006, 0.4044), (0.3736, 0.3874), (0.3670, 0.3578), and (0.3898, 0.3716); said nominal correlated color temperature range for 4500K is circumscribed by the coordinates (0.3736, 0.3874), (0.3546, 0.3736), (0.3512, 0.3465), and (0.3670, 0.3578); said nominal correlated color temperature range for 5000K is circumscribed by the coordinates (0.3551, 0.3760), (0.3376, 0.3616), (0.3366, 0.3369), and (0.3515, 0.3487); said nominal correlated color temperature range for 5700K is circumscribed by the coordinates (0.3376, 0.3616), (0.3207, 0.3462), (0.3222, 0.3243), (0.3366, 0.3369); and said nominal correlated color temperature range for 6500K is circumscribed by the coordinates (0.3205, 0.3481), (0.3028, 0.3304), (0.3068, 0.3113), and (0.3221, 0.3261).
